(19) United States
(12) Patent Application Publication
(10) Pub. No.: US 2025/0112596 A1
(43) Pub. Date: Apr. 3, 2025

(54) ENVELOPE DETECTOR ARCHITECTURE WITH NOISE CANCELATION

(71) Applicant: STMicroelectronics International N.V., Geneva (CH)

(72) Inventors: Alessio Emanuele Vergani, Milano (IT); Francesco Piscitelli, Milano (IT); Michele Bartolini, Carpiano (IT)

(21) Appl. No.: 18/480,322

(22) Filed: Oct. 3, 2023

(51) Int. Cl. H03F 1/02; H03K 5/24; H03K 19/20

(52) U.S. Cl. CPC H03F 1/0233; H03F 2200/165; H03K 5/24; H03K 19/20

(57) ABSTRACT

According to an embodiment, an envelope detector circuit for detecting an envelope of a signal from a sensor in a pre-amplifier circuit of a hard disk drive is provided. The circuit includes a half-wave rectifier, a low-pass filter, and a differential full-wave rectifier. The half-wave rectifier receives a differential voltage from the sensor indicating a fly height of the hard disk drive and generates a pair of single-ended output waveforms based on the differential voltage. Each pair of single-ended output waveforms has a positive polarity for a half-cycle it passes through. The low-pass filter includes a first and a second low-pass filter. The low-pass filter allows low-frequency signals from the pair of single-ended output waveforms to pass through while attenuating or blocking higher-frequency signals. The differential full-wave rectifier reconstructs a differential signal from the low-pass filter while removing DC rectified components.

### TECHNICAL FIELD

The present disclosure generally relates to fly height in a hard disk drive (HDD) and, in particular embodiments, to an envelope detector with noise cancelation in a preamplifier circuit of the hard disk drive.

### BACKGROUND

The distance between a disk drive head of a hard disk drive (HDD) and the platter (i.e., disk) is generally known as the fly height or the head gap. An accurate measurement of the fly height is critical for the performance of the hard disk drive. When the fly height is too large, the read and write errors become excessive, and when the fly height becomes too small, a head crash (i.e., hard disk failure) can occur from, for example, the hard disk drive contacting the disk or rotating platter. As the hard disk drive density increases, the trace width narrows, and the need for an accurate fly height becomes more acute.

Typically, a heating element elevates the temperature of a portion of the disk drive head and distorts the shape. The thermal distortion reduces the fly height of the active read or write elements from 10 to 20 nanometers of normal separation to about 1 nanometer. Thermal sensors measure the fly height by sensing small changes in thermal conductivity as the hard disk drive head nears the disk.

For example, in a hard disk drive with heat-assisted magnetic recording (HAMR), the disk material is temporarily heated to write narrower traces without corrupting nearby stored data. In laser heat-assisted writing, a laser is used to heat the media during the write operation locally—the heated area depends on the laser's wavelength. Typically, a laser-coupled sensor (e.g., laser mode hopping detector) is used to monitor the wavelength of the laser and control the trace width.

Generally, the thermal and laser-coupled sensor measurements are amplified and filtered using, for example, a low-noise analog front-end circuit. The signals' amplitude or magnitude variations are extracted using an envelope detector to control the fly height and detect laser power variations. The envelope represents the “outer shape” or “envelope” of the signal's waveform, capturing its changes in intensity without necessarily preserving the fine details of the waveform itself. Detecting the envelope of a signal can involve a process called envelope detection or amplitude demodulation. The signal is first rectified to remove any negative portions. Then, a low-pass filter is applied to smooth out the variations and capture the envelope.

Conventional envelope detectors use a low-pass filter to process signals with an average zero value at the rectifier's input. This results in a non-zero DC value at the output of the low-pass filter. Noise present at the input of the envelope detector can be simplified as white noise with an average value of zero. When white noise with an average value of zero is rectified and then processed by a low-pass filter, the resulting signal contains a dominant DC component that is not zero. However, the amplitude of this component cannot be accurately predicted due to external noise sources and variations in signal path settings. Consequently, this unpredictability can negatively impact the detection of factors such as head-disk contact, head-disk proximity, and fluctuations in laser power. An improved envelope detector that cures conventional solutions' deficiencies in a pre-amplifier circuit of the hard disk drive is desirable.

### SUMMARY

Technical advantages are generally achieved by embodiments of this disclosure which describe an envelope detector with noise cancelation in a preamplifier circuit of a hard disk drive (HDD).

A first aspect relates to an envelope detector circuit for detecting an envelope of a signal from a sensor in a pre-amplifier circuit of a hard disk drive. The envelope detector circuit includes a half-wave rectifier, a low-pass filter, and a differential full-wave rectifier. The half-wave rectifier is configured to receive a differential voltage from the sensor indicating a fly height of the hard disk drive and generate a pair of single-ended output waveforms based on the differential voltage. Each pair of single-ended output waveforms has a positive polarity for a half-cycle it passes through. The low-pass filter includes a first low-pass filter and a second low-pass filter. The low-pass filter allows low-frequency signals from the pair of single-ended output waveforms to pass through while attenuating or blocking higher-frequency signals. The differential full-wave rectifier is configured to reconstruct a differential signal from the low-pass filter while removing DC rectified components.

A second aspect relates to a pre-amplifier circuit of a hard disk drive, the pre-amplifier circuit includes a sensor configured to measure a fly height of the hard disk drive; a half-wave rectifier configured to receive a differential voltage from the sensor indicating the fly height of the hard disk drive and generate a pair of single-ended output waveforms based on the differential voltage, each of the pair of single-ended output waveforms having a positive polarity for a half-cycle it passes through; a low-pass filter comprising a first low-pass filter and a second low-pass filter, the low-pass filter being configured to allow low-frequency signals from the pair of single-ended output waveforms to pass through while attenuating or blocking higher-frequency signals; and a differential full-wave rectifier configured to reconstruct a differential signal from the low-pass filter while removing DC rectified components.

A third aspect relates to a method for detecting an envelope of a signal from a sensor in a pre-amplifier circuit of a hard disk drive. The method includes receiving, by a half-wave rectifier, a differential voltage from the sensor indicating a fly height of the hard disk drive; generating, by the half-wave rectifier, a pair of single-ended output waveforms based on the differential voltage, each of the pair of single-ended output waveforms having a positive polarity for a half-cycle it passes through; filtering, by a low-pass filter, high-frequency signals from the pair of single-ended output waveforms while passing through low-frequency signals; and reconstructing, by a differential full-wave rectifier, a differential signal from the low-pass filter while removing DC rectified components.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a block diagram of a circuit for biasing a resistive sensor (R_{SNS}) and reading the sensed signal depicted as a voltage source;

FIG. 2 is a block diagram of a conventional envelope detector circuit;

FIG. 3 shows the progression of a non-zero-mean value differential voltage (Vᵢₙ) signal at the input of the conventional envelope detector circuit through the different stages of the circuit;

FIG. 4 shows the progression of a zero-mean value differential voltage (Vᵢₙ) signal at the input of the conventional envelope detector circuit through the different stages of the circuit;

FIG. 5 shows the progression of a noisy differential voltage (Vᵢₙ) signal at the input of the conventional envelope detector circuit through the different stages of the circuit;

FIG. 6 is a block diagram of an embodiment envelope detector circuit;

FIG. 7 shows the progression of a non-zero-mean value differential voltage (Vᵢₙ) signal at the input of the envelope detector circuit of FIG. 6 through the different stages of the circuit;

FIG. 8 shows the operation of an embodiment half-wave rectifier on the non-zero-mean value differential voltage (Vᵢₙ) signal;

FIG. 9 shows the operation of an embodiment differential full-wave rectifier on the non-zero-mean value differential voltage (Vᵢₙ) signal after it is rectified and filtered as the first rectified and filtered signal and the second rectified and filtered signal;

FIG. 10 shows the progression of a zero-mean value differential voltage (Vᵢₙ) signal at the input of the envelope detector circuit of FIG. 6 through the different stages of the circuit;

FIG. 11 shows the progression of a noisy differential voltage (Vᵢₙ) signal at the input of the envelope detector circuit of FIG. 6 through the different stages of the circuit;

FIG. 12 shows the operation of the embodiment half-wave rectifier on the noisy differential voltage (Vᵢₙ) signal;

FIG. 13 shows the operation of an embodiment differential full-wave rectifier on the noisy differential voltage (Vᵢₙ) signal after it is rectified and filtered as the first rectified and filtered signal and the second rectified and filtered signal;

FIG. 14 is a block diagram of a pre-amplifier that is placed on the disk drive head stack assembly of a hard disk drive; and

FIG. 15 is a flow chart of an embodiment method for operating the envelope detector circuit of FIG. 6.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of an envelope detector in a pre-amplifier circuit of a hard disk drive, it should also be appreciated that these inventive aspects may also apply to the processing of other types of signals. In particular, aspects of this disclosure may apply to sensors used for measuring the fly height distance of a disk drive head over a disk or in a preamplifier of a hard disk drive (HDD) device.

The present disclosure provides a new architecture for an envelope detector based on two single-ended half-wave rectifiers, low-pass filters, and a full-wave rectifier. The proposed envelope detector can advantageously return the envelope of any non-zero-mean value input signal. Further, the envelope detector converts zero-mean value signals and zero-mean value white input noise into two equal single-ended signals, resulting in a nulling differential output. In embodiments, the envelope detector acts on signals of interest but cancels input noise to improve the detection process. Aspects of this disclosure provide an envelope detector circuit that generates a lower noise signal at its output, resulting in improved contact and laser power variation detections in the operation of a hard disk drive.

In embodiments, an envelope detector circuit is proposed that maintains the behavior of the signal of interest (i.e., non-zero-mean value signals or signals below the cut-off frequency (f_{c}) of the low-pass filter circuit) while removing the resulting DC value of noise at the output of the low-pass filter circuit. The proposed envelope detector circuit generates an output signal with a zero DC value for a zero-mean value differential (Vᵢₙ) signal at its input, where the frequency (fₛ) of the zero-mean value differential voltage (Vᵢₙ) signal is much greater than the cut-off frequency (f_{c}) of the low-pass filter circuit. Moreover, the proposed envelope detector circuit generates an output signal with a zero DC value for a noisy differential voltage (Vᵢₙ) signal at its input by canceling the rectified and low-pass filtered white noise. These and other details are further detailed below.

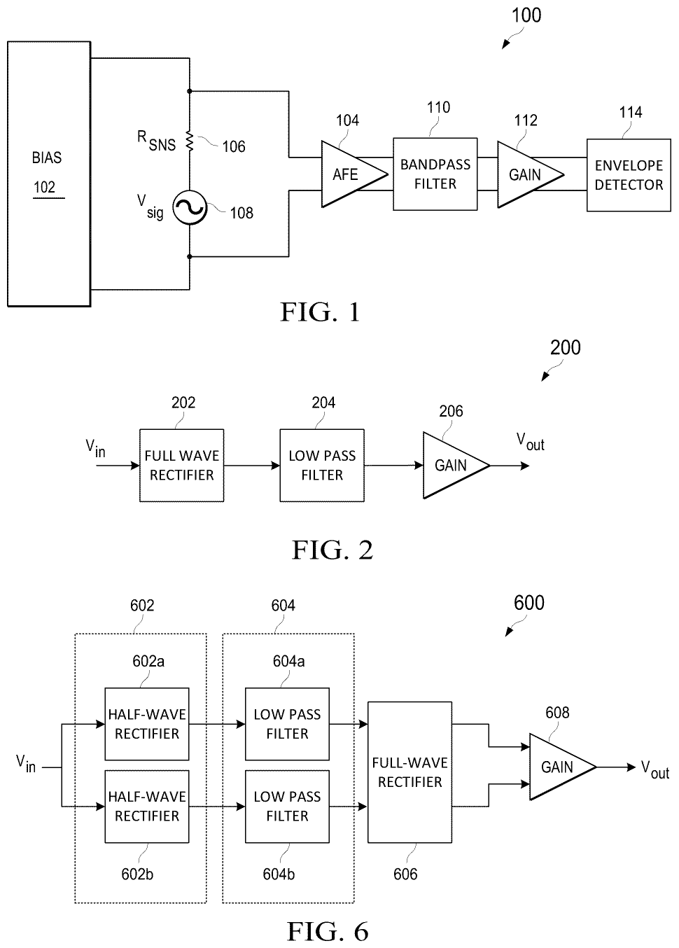

FIG. 1 illustrates a block diagram of circuit 100 for biasing a resistive sensor (R_{SNS}) 106 and reading the sensed signal depicted as voltage source 108. Circuit 100 includes a biasing circuit 102 and an analog front-end (AFE) circuit 104 coupled to the resistive sensor 106, which may (or may not) be arranged as shown. The analog front-end circuit 104 is coupled to a bandpass filter circuit 110, a gain stage circuit 112, and an envelope detector circuit 114. Circuit 100 may include additional components not shown. A detailed description of circuit 100 is provided in U.S. Pat. No. 10,965,254, which is incorporated herein by reference in its entirety.

Sensors are widely used devices in electronic systems to measure different physical quantities, such as temperature, pressure, and force. Resistive elements are commonly used as sensors due to their inexpensive fabrication and simple interfacing with signal-conditioning circuits.

The resistive sensor 106, commonly represented as a thermal varying resistor, is placed on the read and write head of the hard disk drive. The resistive sensor 106 monitors the fly height between the disk drive head and the disk itself. To operate the hard disk drive properly, the resistive sensor 106 is biased with a constant voltage (or current). In response to the disk drive head approaching the disk, the disk acts as a heat sinker. The resistance of the resistive sensor 106 varies from the heat, represented as the voltage signal (V_{sig}) or a current associated with the resistive sensor 106. The voltage signal (V_{sig}) is filtered and amplified to measure the fly height precisely. Proper filtering and amplification become crucial as the voltage signal (V_{sig}) is typically small.

The biasing circuit 102 is coupled to the resistive sensor 106. Biasing circuit 102 applies a voltage (or current) bias to resistive sensor 106. The analog front-end circuit 104 amplifies the sensing voltage (V_{sig}). The output of the analog front-end circuit 104 is coupled to a controller that processes the amplified sensing voltage (V_{sig}) to determine, for example, the fly height of the hard disk drive.

Conventionally, voltage dividers or Wheatstone bridges have been used to bias the resistive sensor 106. Disadvantageously, process variations in the resistive sensor 106 and the circuit biasing components significantly impact the accuracy (i.e., inaccuracy) of the bias voltage applied to the resistive sensor 106. The adverse impact is more substantial when biasing a low-resistance resistive sensor (i.e., low resistance sensors). Calibration of the bias circuit is, thus, required to provide an accurate desired bias voltage. However, calibration of the bias circuit is undesirable due to the added cost and time associated with calibrating the circuit in production.

The biasing circuit 102 should drive significant currents with low noise, typically requiring components that take a sizable circuit footprint. Further, it is desirable for the biasing circuit 102 to have a low bandwidth (i.e., low bias circuit cut-off frequency), preferably lower than the bandwidth of the analog front-end circuit 104, which requires components that take a sizable circuit footprint.

It is also desirable for the analog front-end circuit 104 to have low noise and a wide bandwidth transfer function to process the sensing voltage (V_{sig}), which requires components with a significant circuit footprint.

The resistive sensor 106, thus, is biased using an analog loop, which typically has a bandwidth in the tens of kilohertz. Generally, sensing voltage (V_{sig}) signals higher than the bias bandwidth (i.e., high-frequency component (V_{HF})) can be extracted, amplified, and processed. However, it is desirable to extract the sensing voltage (V_{sig}) signals lower than the bias bandwidth (i.e., low-frequency component (V_{LF})−DC to bias bandwidth).

The bandpass filter circuit 110, gain stage circuit 112, and envelope detector circuit filter, amplify, and extract the amplitude or magnitude of the sensing voltage (V_{sig}).

FIG. 2 illustrates a block diagram of a conventional envelope detector circuit 200, which may be implemented as the envelope detector circuit 114 in circuit 100. Conventional envelope detector circuit 200 includes a differential full-wave rectifier 202, a low-pass filter circuit 204, and a gain stage circuit 206. The conventional envelope detector circuit 200 is configured to capture the intensity changes of the differential voltage (Vᵢₙ) from the gain stage circuit 112 and extract the amplitude or magnitude (Vₒᵤₜ).

Differential full-wave rectifier 202 is configured to rectify the differential voltage (Vᵢₙ) and generate an output waveform with positive voltages (or possibly near-zero voltages for very small negative input voltages) with minimal distortion. In embodiments, the differential full-wave rectifier 202 is configured to operate at up to tens of megahertz (MHz).

Differential full-wave rectifier 202 may be arranged as known in the art. For example, differential full-wave rectifier 202 may include operational amplifiers (op-amps) to amplify and process the differential voltage (Vᵢₙ), diodes (e.g., four diodes) to rectify the differential voltage (Vᵢₙ), a feedback network using resistors and capacitors to control the operation of the op-amp and ensuring the accuracy of the rectification process and maintaining the correct voltage levels, and a reference voltage source to provide a stable reference level for the rectification process.

The low-pass filter circuit 204 is configured to allow low-frequency signals from the differential full-wave rectifier 202 to pass through while attenuating or blocking higher-frequency signals. The low-pass filter circuit 204 may be arranged as known in the art. For example, low-pass filter circuit 204 may include one or more resistors to control the flow of current and one or more capacitors to store and release energy. In embodiments, the low-pass filter circuit 204 is a second-order low-pass filter. In embodiments, the low-pass filter circuit 204 is adjustable, and the cut-off frequency (f_{c}) of the low-pass filter circuit 204 can be adjusted from, for example, tens of kilohertz (kHz) to hundreds of kHz.

Gain stage circuit 206 is configured to amplify the amplitude of the filtered signal from the low-pass filter circuit 204 without modifying the shape and characteristics of the filtered signal. Gain stage circuit 206 may be arranged as known in the art. For example, gain stage circuit 206 may include an active component, such as a transistor or an op-amp, and passive components, such as resistors and capacitors. In embodiments, the gain stage circuit 206 is configured to have selectable gain.

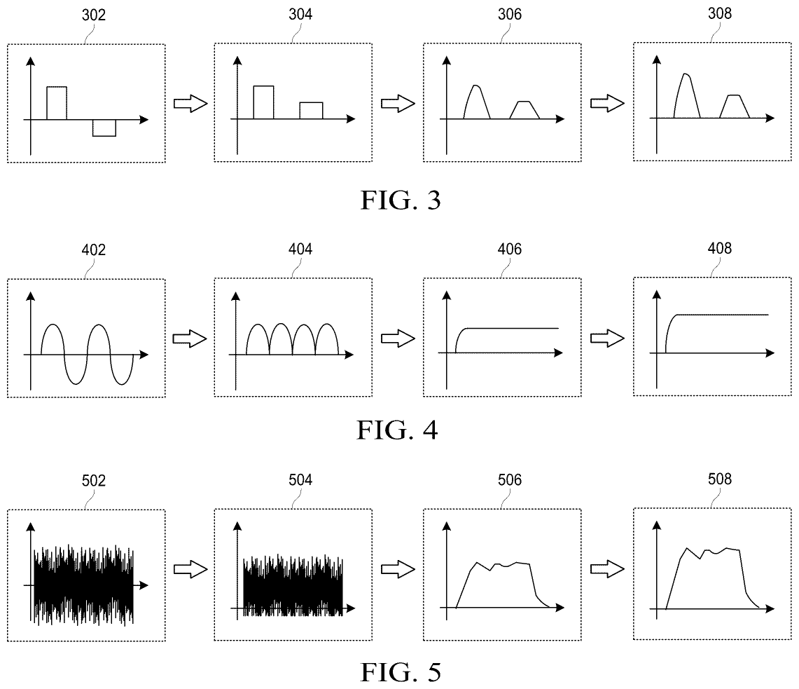

FIG. 3 illustrates the progression of a non-zero-mean value differential voltage (Vᵢₙ) signal 302 at the input of the conventional envelope detector circuit 200 through the different stages of the circuit. The example of the non-zero-mean value differential voltage (Vᵢₙ) signal 302 in FIG. 3 is represented as differential pulses with a positive and a negative input pulse.

The differential full-wave rectifier 202 rectifies the non-zero-mean value differential voltage (Vᵢₙ) signal 302 to generate rectified signal 304 with only positive polarity. The low-pass filter circuit 204 filters the rectified signal 304 to generate the rectified and filtered signal 306. The low-pass filter circuit 204 is configured to filter out frequencies greater than the cut-off frequency (f_{c}) of the low-pass filter circuit 204 and provide a smooth in-band response for the rectified and filtered signal 306. The gain stage circuit 206 amplifies the rectified and filtered signal 306 to generate rectified, filtered, and amplified signal 308 as the output voltage (Vₒᵤₜ) of the conventional envelope detector circuit 200.

FIG. 4 illustrates the progression of a zero-mean value differential voltage (Vᵢₙ) signal 402 at the input of the conventional envelope detector circuit 200 through the different stages of the circuit. The example of the zero-mean value differential voltage (Vᵢₙ) signal 402 in FIG. 4 is represented as a sinusoidal signal with a frequency (fₛ) and a peak amplitude (Vₚₑₐₖ). The frequency (fₛ) of the zero-mean value differential voltage (Vᵢₙ) signal 402 is much greater than the cut-off frequency (f_{c}) of the low-pass filter circuit 204.

The differential full-wave rectifier 202 rectifies the zero-mean value differential voltage (Vᵢₙ) signal 402 to generate rectified signal 404 with only positive polarity. The low-pass filter circuit 204 filters the rectified signal 404 to generate the rectified and filtered signal 406. The low-pass filter circuit 204 is configured to filter out frequencies greater than the cut-off frequency (f_{c}) of the low-pass filter circuit 204 and provide a smooth in-band response for the rectified and filtered signal 406. The gain stage circuit 206 amplifies the rectified and filtered signal 406 to generate rectified, filtered, and amplified signal 408 as the output voltage (Vₒᵤₜ) of the conventional envelope detector circuit 200. The rectified, filtered, and amplified signal 408 is a non-nulling signal with a DC voltage value (V_{DC}) equal to the average of the rectified signal:

$${V}_{DC} = \frac{{V}_{peak}}{π} .$$

Disadvantageously, the conventional envelope detector circuit 200 generates a non-null signal for a zero-mean value at the input of the differential full-wave rectifier 202.

FIG. 5 illustrates the progression of a noisy differential voltage (Vᵢₙ) signal 502 at the input of the conventional envelope detector circuit 200 through the different stages of the circuit. The example of the noisy differential voltage (Vᵢₙ) signal 502 in FIG. 5 is represented as a zero-mean value signal with a bandwidth typically much greater than the cut-off frequency (f_{c}) of the low-pass filter circuit 204 (i.e., the noise being from low to high frequencies).

The differential full-wave rectifier 202 rectifies the noisy differential voltage (Vᵢₙ) signal 502 to generate rectified signal 504 with only positive polarity. The low-pass filter circuit 204 filters the rectified signal 504 to generate the rectified and filtered signal 506. The low-pass filter circuit 204 is configured to filter out frequencies greater than the cut-off frequency (f_{c}) of the low-pass filter circuit 204 and provide a smooth response for the rectified and filtered signal 506 by averaging out-of-band noise. The gain stage circuit 206 amplifies the rectified and filtered signal 506 to generate rectified, filtered, and amplified signal 508 as the output voltage (Vₒᵤₜ) of the conventional envelope detector circuit 200. The rectified, filtered, and amplified signal 508 is a non-null signal as the averaged and low-frequency noise are present at the output of the low-pass filter circuit 204. Disadvantageously, the conventional envelope detector circuit 200 generates a non-null signal (i.e., with a DC value greater than zero) for the noisy signal at the input of the differential full-wave rectifier 202.

As shown in FIGS. 4 and 5, the conventional envelope detector circuit 200 is unable to eliminate the zero-mean value differential voltage (Vᵢₙ) signal 402 and the noisy differential voltage (Vᵢₙ) signal 502 after the rectification and filtering without altering the envelope of the differential voltage (Vᵢₙ), which negatively affects the detection of head-disk contact and laser power variation. Embodiments of this disclosure provide an improved envelope detector circuit that nullifies the zero-mean value differential voltage (Vᵢₙ) signal 402 and the noisy differential voltage (Vᵢₙ) signal 502 without altering the envelope of the differential voltage (Vᵢₙ).

FIG. 6 illustrates a block diagram of an embodiment envelope detector circuit 600, which may be implemented as the envelope detector circuit 114 in circuit 100. Envelope detector circuit 600 includes half-wave rectifier 602, low-pass filter circuit 604, a differential full-wave rectifier 606, and an optional gain stage circuit 608, which may (or may not) be arranged as shown. Envelope detector circuit 600 may include additional components not shown. The envelope detector circuit 600 is configured to capture the intensity changes of the differential voltage (Vᵢₙ) from the gain stage circuit 112 and extract the amplitude or magnitude (Vₒᵤₜ) without the deficiencies in the conventional envelope detector circuit 200.

Each half-wave rectifier 602a-b is configured to generate a corresponding single-ended output waveform with positive voltage with minimal distortion. In embodiments, half-wave rectifier 602 is configured to operate at up to tens of megahertz (MHz). For example, half-wave rectifier 602 is configured to operate between DC and tens of MHz.

A first half-wave rectifier 602a operates on the positive portions of the differential voltage (Vᵢₙ). In embodiments, the first half-wave rectifier 602a allows positive half-cycles of the differential voltage (Vᵢₙ) to pass through while blocking negative half-cycles (i.e., series of positive half-cycles with the negative half-cycles removed). A second half-wave rectifier 602b operates on the negative portions of the differential voltage (Vᵢₙ). In embodiments, the second half-wave rectifier 602b allows negative half-cycles of the differential voltage (Vᵢₙ) to pass through while blocking positive half-cycles (i.e., series of negative half-cycles with the positive half-cycles removed, where the polarity of the negative half-cycles are reversed). Each half-wave rectifier 602a-b generates a corresponding single-ended output waveform with the same positive polarity for the half-cycle it passes through but phase shifted by 180°.

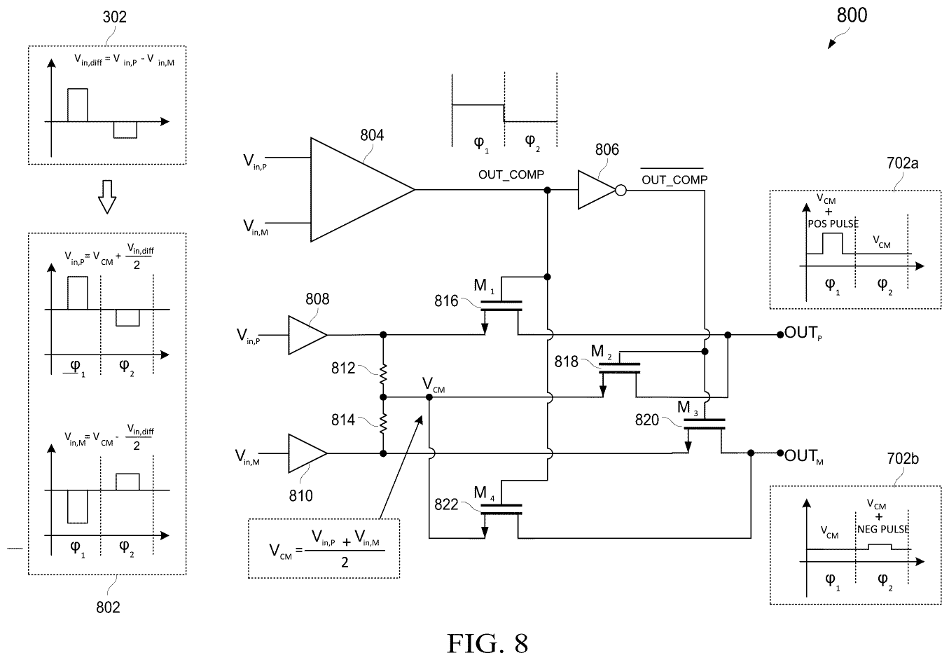

Half-wave rectifier 602 may be arranged as known in the art. FIG. 8 illustrates an embodiment half-wave rectifier 800, which may be implemented as the half-wave rectifier 602.

Low-pass filter circuit 604 is configured to allow low-frequency signals from the half-wave rectifier 602 to pass through while attenuating or blocking higher-frequency signals. Low-pass filter circuit 604 may be arranged as known in the art. For example, each low-pass filter circuit 604a-b may include one or more resistors to control the flow of current and one or more capacitors to store and release energy. In embodiments, low-pass filter circuit 604 is a second-order low-pass filter. In embodiments, low-pass filter circuit 604 is adjustable, and the cut-off frequency (f_{c}) of low-pass filter circuit 604 can be adjusted from, for example, tens of kilohertz (kHz) to hundreds of kHz.

In the case of the high-frequency zero-mean value differential voltage (Vᵢₙ) signal (i.e., the frequency (fₛ) of the zero-mean value differential voltage (Vᵢₙ) signal being much greater than the cut-off frequency (f_{c}) of the low-pass filter circuit), the output of each low-pass filter circuit 604a-b includes a DC signal component with the same amplitude.

Differential full-wave rectifier 606 is configured to reconstruct a differential signal while removing the DC rectified components and achieving full rectification of the input signals. Differential full-wave rectifier 606 operates on the respective output signals of each low-pass filter circuit 604a-b, which includes the DC signal component with the same amplitude. Accordingly, the differential full-wave rectifier 606 provides noise cancellation on zero-mean value differential voltage signals.

In embodiments, the differential full-wave rectifier 606 is configured to operate at up to tens of megahertz (MHz). For example, differential full-wave rectifier 606 is configured to operate between DC and tens of MHz.

Differential full-wave rectifier 606 may be arranged as known in the art. For example, differential full-wave rectifier 606 may include operational amplifiers (op-amps) to amplify and process the differential voltage (Vᵢₙ), diodes (e.g., four diodes) to rectify the differential voltage (Vᵢₙ), a feedback network using resistors and capacitors to control the operation of the op-amp and ensuring the accuracy of the rectification process and maintaining the correct voltage levels, and a reference voltage source to provide a stable reference level for the rectification process. In embodiments, the differential full-wave rectifier 606 has the same structural and functional features as the differential full-wave rectifier 202 in the conventional envelope detector circuit 200.

Gain stage circuit 608 is configured to amplify the amplitude of the output waveform from the differential full-wave rectifier 606 without modifying the shape and characteristics of the filtered signal. Gain stage circuit 608 may be arranged as known in the art. For example, gain stage circuit 608 may include an active component, such as a transistor or an op-amp, and passive components, such as resistors and capacitors. In embodiments, the gain stage circuit 608 is configured to have selectable gain.

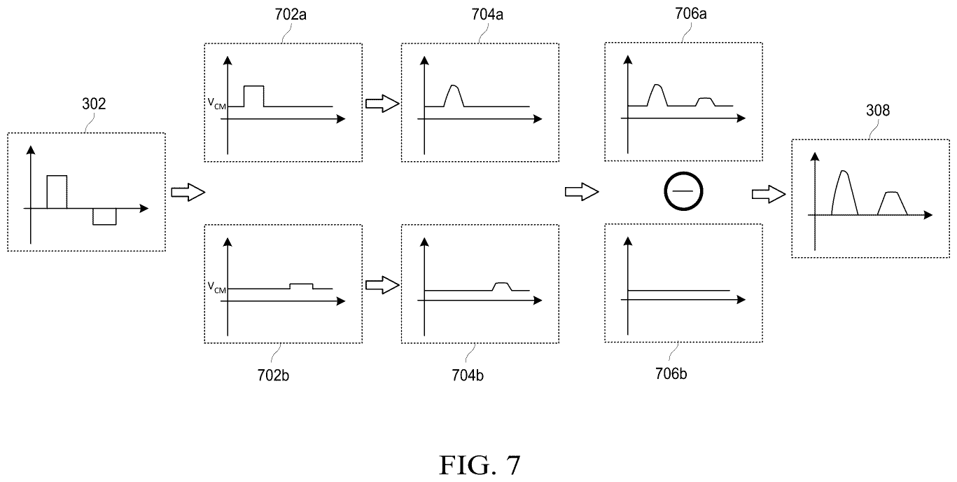

FIG. 7 illustrates the progression of a non-zero-mean value differential voltage (Vᵢₙ) signal 302 at the input of the envelope detector circuit 600 through the different stages of the circuit. The example of the non-zero-mean value differential voltage (Vᵢₙ) signal 302 in FIG. 7 is represented as differential pulses with a positive and a negative input pulse.

The first half-wave rectifier 602a rectifies the positive half-cycles of the non-zero-mean value differential voltage (Vᵢₙ) signal 302 while blocking negative half-cycles. The output signal of the first half-wave rectifier 602a is illustrated as the first rectified signal 702a, which is a single-ended, positive pulse with a common-mode voltage (V_{cm}). The second half-wave rectifier 602b rectifies the negative half-cycles of the non-zero-mean value differential voltage (Vᵢₙ) signal 302 while blocking positive half-cycles. The output signal of the second half-wave rectifier 602b is illustrated as the second rectified signal 702b, which is a single-ended, positive pulse with a common-mode voltage (V_{CM}). The common-mode voltage (V_{CM}) is an arbitrary voltage level equal the half-wave rectifiers 602a-b. In embodiments, the common-mode voltage (V_{CM}) is the common-mode signal of the input signal. The operation of each half-wave rectifier 602a-b on the non-zero-mean value differential voltage (Vᵢₙ) signal 302 is detailed in FIG. 8.

The first low-pass filter circuit 604a filters the first rectified signal 702a while smoothing the in-band component to generate the first rectified and filtered signal 704a. The second low-pass filter circuit 604b filters the second rectified signal 702b while smoothing the in-band component to generate the second rectified and filtered signal 704b. Each low-pass filter circuit 604a-b is configured to filter out frequencies greater than the cut-off frequency (f_{c}) of the low-pass filter circuit 604a-b and provide a smooth response for the first rectified and filtered signal 704a and the second rectified and filtered signal 704b.

Differential full-wave rectifier 606 is configured to recombine the single-ended first rectified and filtered signal 704a and the second rectified and filtered signal 704b, which is then amplified by the gain stage circuit 608 to obtain the amplified signal 308 as the output voltage (Vₒᵤₜ) of the envelope detector circuit 600, similar to the output signal at the output of the conventional envelope detector circuit 200. In embodiments, the positive output terminal of the differential full-wave rectifier 606 includes the positive pulse, the negative pulse, and the common-mode voltage (V_{CM}). In embodiments, the negative terminal of the differential full-wave rectifier 606 includes only the common-mode voltage (V_{CM}). In embodiments, the difference between the signal at the positive output terminal of the differential full-wave rectifier 606 and the signal at the negative output terminal of the differential full-wave rectifier 606 is provided at the input of the gain stage circuit 608. Thus, the envelope detector circuit 700 behaves similarly to the conventional envelope detector circuit 200 for non-zero-mean value differential voltage (Vᵢₙ) signals.

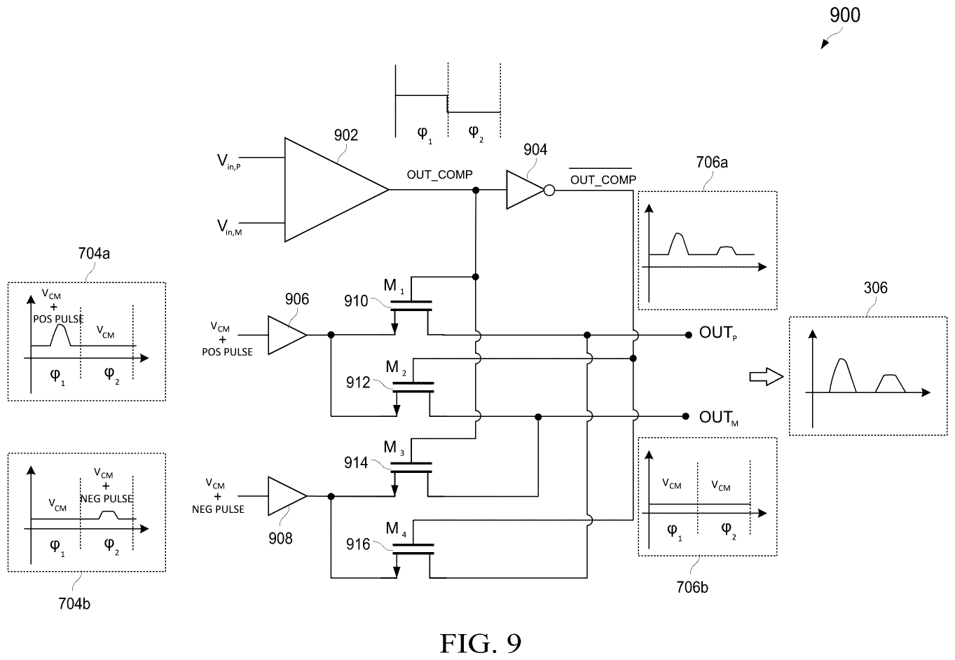

In embodiments, the gain stage circuit 608 is a differential gain stage. In embodiments, the input to the gain stage circuit 608 is the difference between the differential rectified and filtered signal 706a and the common-mode voltage signal 706b. As the differential rectified and filtered signal 706a includes the common-mode voltage (V_{CM}), the subtraction of the differential rectified and filtered signal 706a from the common-mode voltage signal 706b results in a signal similar to the rectified and filtered signal 306 in FIG. 3. The operation of the differential full-wave rectifier 606 on the single-ended first rectified and filtered signal 704a and the second rectified and filtered signal 704b are detailed in FIG. 9.

FIG. 8 illustrates the operation of an embodiment half-wave rectifier 800 on the non-zero-mean value differential voltage (Vᵢₙ) signal 302. Half-wave rectifier 800 may be implemented as the half-wave rectifier 602 in the envelope detector circuit 600. As shown, half-wave rectifier 800 includes a comparator 804, an inverter 806, a positive-side buffer circuit 808, a negative-side buffer circuit 810, a first resistor 812, a second resistor 814, a first transistor 816, a second transistor 818, a third transistor 820, and a fourth transistor 822, which may (or may not) be arranged as shown. Half-wave rectifier 800 may include additional components not shown.

The non-zero-mean value differential voltage (Vᵢₙ) signal 302, at the input terminal of the half-wave rectifier 800 is represented as two pulses: (i) a pulse with a voltage amplitude of V_{in,P}, equal to V_{cm}+V_{in,diff}/2 and (ii) a pulse with a voltage amplitude of V_{in,M}, equal to V_{cm}+V_{in,diff}/2. The non-zero-mean value differential voltage (Vᵢₙ) signal 302 can be represented with the equation (1): V_{in,diff}=V_{in,P}−V_{in,M}.

The comparator 804 and the inverter 806 provide control signals for the gate terminals of the first transistor 816, second transistor 818, third transistor 820, and fourth transistor 822, depending on the phase of operation (i.e., phase φ₁ and phase φ₂). In embodiments, the pulse input V_{in,P} is provided at the non-inverted terminal of the comparator 804 and the pulse input V_{in,M} is provided at the inverted terminal of the comparator 804. The output of the comparator 804 is the output signal (OUT_COMP), fed to the input of the inverter 806 and the gate terminals of the first transistor 816 and the fourth transistor 822. The output signal (OUT_COMP) of the inverter 806 is the reverse polarity of the output signal (OUT_COMP) from the comparator 804, fed to the gate terminals of the second transistor 818 and the third transistor 820.

The arrangement of the first resistor 812 and the second resistor 814 at the output of the positive-side buffer circuit 808 and the negative-side buffer circuit 810 provides a relationship between the input signals at the positive-side buffer circuit 808 and the negative-side buffer circuit 810. Assuming that the input signal at the positive-side buffer circuit 808 is the pulse input V_{in,P} and the input signal to the negative-side buffer circuit 810 is the pulse input V_{in, M}, the common-mode voltage (V_{cm}) can be represented with the equation (2):

$${V}_{cm} = \frac{{V}_{in , P} + {V}_{in , M}}{2} .$$

Based on equations (1) and (2), the pulse input V_{in,P} can be represented with the equation (3):

$${V}_{in , P} = {V}_{cm} + \frac{{V}_{in , diff}}{2}$$

and the pulse input V_{in,M} can be represented with the equation (4):

$${V}_{in , M} = {V}_{cm} - \frac{{V}_{in , diff}}{2} .$$

During the phase φ1, the pulse input V_{in,P} is greater than the pulse input V_{in, M}; thus, the output signal (OUT_COMP) of comparator 804 is at a logic level high and the output signal (OUT_COMP) of inverter 806 is at a logic level low. As such, the first transistor 816 and the fourth transistor 822 are in the CLOSE position, while the second transistor 818 and the third transistor 820 are in the OPEN position. The positive output signal (OUT_{P}), corresponding to the first rectified signal 702a, has a value equal to the common-mode voltage (V_{cm}) plus the pulse with positive-polarity of input V_{in,P} (i.e., the positive output signal (OUT_{P}) is equal to V_{in,P} during phase φ₁). The negative output signal (OUT_{M}), corresponding to the second rectified signal 702b, is equal to the common-mode voltage (V_{cm}).

During the phase φ₂, the pulse input V_{in,P} is less than the pulse input V_{in, M}; thus, the output signal (OUT_COMP) of comparator 804 is at a logic level low and the output signal (O̅U̅T̅_̅C̅O̅M̅P̅) of inverter 806 is at a logic level high. Accordingly, the first transistor 816 and the fourth transistor 822 are in the OPEN position, whereas the second transistor 818 and the third transistor 820 are in the CLOSE position. The positive output signal (OUT_{P}), corresponding to the first rectified signal 702a, is equal to the common-mode voltage (V_{cm}). The negative output signal (OUT_{M}), corresponding to the second rectified signal 702b, has a value equal to the common-mode voltage (V_{cm}) plus the pulse with positive-polarity of input V_{in,M} (i.e., the negative output signal (OUT_{M}) is equal to V_{in,M} during phase φ₂).

FIG. 9 illustrates the operation of an embodiment differential full-wave rectifier 900 on the non-zero-mean value differential voltage (Vᵢₙ) signal 302 after it is rectified and filtered as the first rectified and filtered signal 704a and the second rectified and filtered signal 704b. Differential full-wave rectifier 900 may be implemented as the differential full-wave rectifier 606 in the envelope detector circuit 600. As shown, differential full-wave rectifier 900 includes a comparator 902, an inverter 904, a positive-side buffer circuit 906, a negative-side buffer circuit 908, a first transistor 910, a second transistor 912, a third transistor 914, and a fourth transistor 916, which may (or may not) be arranged as shown. Differential full-wave rectifier 900 may include additional components not shown.

The comparator 902 and the inverter 904 provide control signals for the gate terminals of the first transistor 910, second transistor 912, third transistor 914, and fourth transistor 916, depending on the phase of operation (i.e., phase φ₁ and phase φ₂). In embodiments, the pulse input V_{in,P} is provided at the non-inverted terminal of the comparator 902 and the pulse input V_{in, M} is provided at the inverted terminal of the comparator 902. The output of the comparator 902 is the output signal (OUT_COMP), fed to the input of the inverter 904 and the gate terminals of the first transistor 910 and the third transistor 914. The output signal (O̅U̅T̅_̅C̅O̅M̅P̅)̅ of inverter 904 is the reverse polarity of the output signal (OUT_COMP) from the comparator 902, fed to the gate terminals of the second transistor 912 and the fourth transistor 916.

The input to the positive-side buffer circuit 906 is the first rectified and filtered signal 704a. The input to the negative-side buffer circuit 908 is the second rectified and filtered signal 704b.

During the phase φ₁, the pulse input V_{in,P} is greater than the pulse input V_{in, M}; thus, the output signal (OUT_COMP) of comparator 902 is at a logic level high and the output signal (O̅U̅T̅_̅C̅O̅M̅P̅) of inverter 904 is at a logic level low. As such, the first transistor 910 and the third transistor 914 are in the CLOSE position, while the second transistor 912 and the fourth transistor 916 are in the OPEN position. The positive output signal (OUT_{P}), corresponding to the differential rectified and filtered signal 706a, has a value equal to the common-mode voltage (V_{cm}) plus the pulse with positive-polarity of input V_{in,P} (i.e., the positive output signal (OUT_{P}) is equal to V_{in,P} during phase φ₁). The negative output signal (OUT_{M}), corresponding to the common-mode voltage signal 706b, equals the common-mode voltage (V_{cm}).

During the phase φ₂, the pulse input V_{in,P} is less than the pulse input V_{in, M}; thus, the output signal (OUT_COMP) of comparator 902 is at a logic level low and the output signal (O̅U̅T̅_̅C̅O̅M̅P̅) of inverter 904 is at a logic level high. Accordingly, the first transistor 910 and the third transistor 914 are in the OPEN position, whereas the second transistor 912 and the fourth transistor 916 are in the CLOSE position. The positive output signal (OUT_{P}), corresponding to the differential rectified and filtered signal 706a, is equal to the common-mode voltage (V_{cm}) plus the pulse with positive-polarity of input V_{in,M} (i.e., the positive output signal (OUT_{P}) is equal to V_{in,M} during phase φ₂). The negative output signal (OUT_{M}), corresponding to the common-mode voltage signal 706b, equals the common-mode voltage (V_{cm}). As the differential rectified and filtered signal 706a includes the common-mode voltage (V_{CM}), the subtraction of the differential rectified and filtered signal 706a from the common-mode voltage signal 706b results in a signal similar to the rectified and filtered signal 306 in FIG. 3.

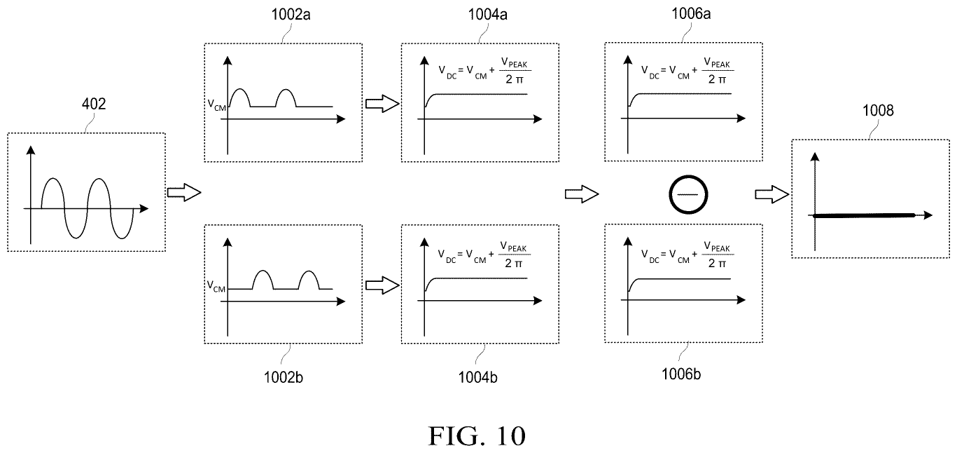

FIG. 10 illustrates the progression of a zero-mean value differential voltage (Vᵢₙ) signal 402 at the input of the envelope detector circuit 600 through the different stages of the circuit. The example of the zero-mean value differential voltage (Vᵢₙ) signal 402 in FIG. 10 is represented as a sinusoidal signal with a frequency (fₛ) and a peak amplitude (Vₚₑₐₖ). The frequency (fₛ) of the zero-mean value differential voltage (Vᵢₙ) signal 402 is much greater than the cut-off frequency (f_{c}) of each low-pass filter circuit 604a-b.

The first half-wave rectifier 602a rectifies the positive half-cycles of the zero-mean value differential voltage (Vᵢₙ) signal 402 while blocking negative half-cycles. The output signal of the first half-wave rectifier 602a is illustrated as the first rectified signal 1002a, which is a single-ended, positive half-wave signal with a common-mode voltage (V_{CM}). The second half-wave rectifier 602b rectifies the negative half-cycles of the non-zero-mean value differential voltage (Vᵢₙ) signal 402 while blocking positive half-cycles. The output signal of the second half-wave rectifier 602b is illustrated as the second rectified signal 1002b, which is a single-ended, positive half-wave signal with a common-mode voltage (V_{cm}). The first rectified signal 1002a and the second rectified signal 1002b have the same positive polarity but are shifted by 180°.

The first low-pass filter circuit 604a filters the first rectified signal 1002a to generate the first rectified and filtered signal 1004a. The second low-pass filter circuit 604b filters the second rectified signal 1002b to generate the second rectified and filtered signal 1004b. Each low-pass filter circuit 604a-b is configured to filter out frequencies greater than the cut-off frequency (f_{c}) of the low-pass filter circuit 604a-b and provide a smooth response for the first rectified and filtered signal 1004a and the second rectified and filtered signal 1004b. As the frequency (fₛ) of the zero-mean value differential voltage (Vᵢₙ) signal 402 is much greater than the cut-off frequency (f_{c}) of each low-pass filter circuit 604a-b, each of the first rectified and filtered signal 1004a and the second rectified and filtered signal 1004b are represented by a signal (V_{DC}) that is equal to the sum of the common-mode voltage (V_{CM}) and the average of the rectified signal:

$${V}_{DC} = {V}_{CM} + \frac{{V}_{peak}}{2 π} .$$

Differential full-wave rectifier 606 is configured to recombine the single-ended first rectified and filtered signal 1004a and the second rectified and filtered signal 1004b, which is then amplified by the gain stage circuit 608 to obtain the amplified signal 1008 as the output voltage (Vₒᵤₜ) of the envelope detector circuit 600. In contrast with the conventional envelope detector circuit 200, where its output voltage (Vₒᵤₜ) was a non-nulling signal with a DC voltage value (V_{DC}) equal to the average of the rectified signal:

$${V}_{DC} = \frac{{V}_{peak}}{π} ,$$

in the envelope detector circuit 600, the output voltage (Vₒᵤₜ) is, advantageously, a null differential signal.

The input to the gain stage circuit 608 is the difference between the first differential rectified and filtered signal 1006a and the second differential rectified and filtered signal 1006b. As the first differential rectified and filtered signal 1006a is equal in magnitude and shape to the second differential rectified and filtered signal 1006b, the subtraction of the two signals results in a null signal.

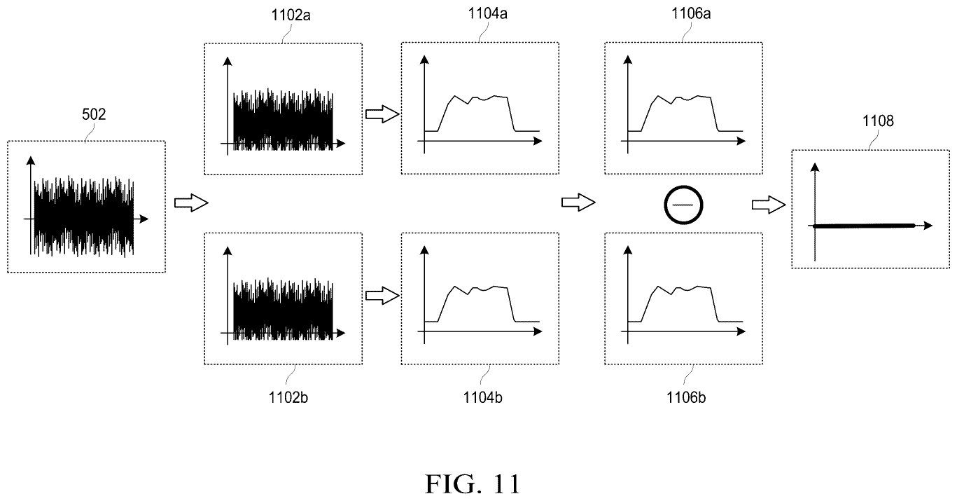

FIG. 11 illustrates the progression of a noisy differential voltage (Vᵢₙ) signal 502 at the input of the envelope detector circuit 600 through the different stages of the circuit. The example of the noisy differential voltage (Vᵢₙ) signal 502 in FIG. 11 is represented as a zero-mean value signal with a bandwidth typically much greater than the cut-off frequency (f_{c}) of each low-pass filter circuit 604a-b.

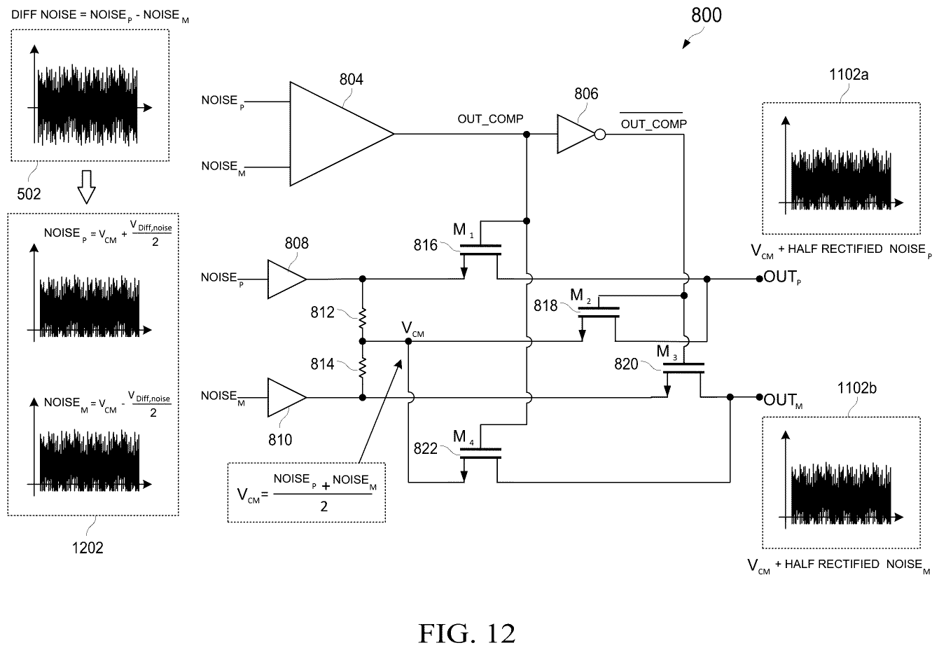

The first half-wave rectifier 602a rectifies the positive portions of the noisy differential voltage (Vᵢₙ) signal 502 while blocking negative portions. The output signal of the first half-wave rectifier 602a is illustrated as the first rectified signal 1102a, which is a single-ended, positive signal with a common-mode voltage (V_{CM}). The second half-wave rectifier 602b rectifies the negative portions of the noisy differential voltage (Vᵢₙ) signal 502 while blocking positive portions. The output signal of the second half-wave rectifier 602b is illustrated as the second rectified signal 1102b, which is a single-ended, positive signal with a common-mode voltage (V_{cm}). The first rectified signal 1102a and the second rectified signal 1102b have the same positive polarity. The operation of each half-wave rectifier 602a-b on the noisy differential voltage (Vᵢₙ) signal 502 is detailed in FIG. 12.

The first low-pass filter circuit 604a filters the first rectified signal 1102a to generate the first rectified and filtered signal 1104a. The second low-pass filter circuit 604b filters the second rectified signal 1102b to generate the second rectified and filtered signal 1104b. Each low-pass filter circuit 604a-b is configured to filter out frequencies greater than the cut-off frequency (f_{c}) of the low-pass filter circuit 604a-b and provide a smooth response for the first rectified and filtered signal 1104a and the second rectified and filtered signal 1104b, by averaging the out-of-band noise.

Differential full-wave rectifier 606 is configured to recombine the single-ended first rectified and filtered signal 1104a and the second rectified and filtered signal 1104b, which is then amplified by the gain stage circuit 608 to obtain the amplified signal 1108 as the output voltage (Vₒᵤₜ) of the envelope detector circuit 600. In contrast with the conventional envelope detector circuit 200, where its output voltage (Vₒᵤₜ) was a non-nulling signal, in the envelope detector circuit 600, the output voltage (Vₒᵤₜ) is, advantageously, a null differential signal.

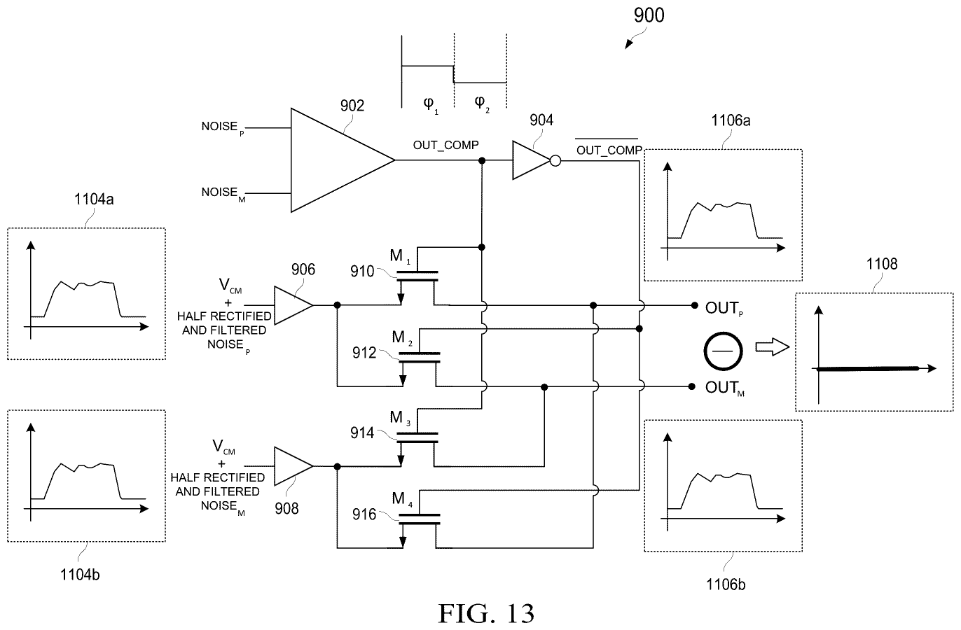

The input to the gain stage circuit 608 is the difference between the first differential rectified and filtered signal 1106a and the second differential rectified and filtered signal 1106b. As the first differential rectified and filtered signal 1106a is substantially equal in magnitude and shape to the second differential rectified and filtered signal 1106b, the subtraction of the two signals results in a null signal. The operation of the differential full-wave rectifier 606 on the single-ended first rectified and filtered signal 1104a and the second rectified and filtered signal 1104b are detailed in FIG. 13.

FIG. 12 illustrates the operation of the embodiment half-wave rectifier 800 on the noisy differential voltage (Vᵢₙ) signal 502. The noisy differential voltage (Vᵢₙ) signal 502 can be represented with the equation (5): V_{in,diff}=NOISE_{P}−NOISE_{M}.

The arrangement of the first resistor 812 and the second resistor 814 at the output of the positive-side buffer circuit 808 and the negative-side buffer circuit 810 provides a relationship between the input signals at the positive-side buffer circuit 808 and the negative-side buffer circuit 810. Assuming that the input signal at the positive-side buffer circuit 808 is Noise_{P} signal and the input signal to the negative-side buffer circuit 810 is Noise_{M} signal, the common-mode voltage (V_{cm}) can be represented with the equation (6):

$${V}_{cm} = \frac{{NOISE}_{P} + {NOISE}_{M}}{2} .$$

Based on equations (5) and (6), Noise_{P} signal can be represented with the equation (7):

$${NOISE}_{P} = {V}_{cm} + \frac{{V}_{in , diff}}{2}$$

and Noise_{M} signal can be represented with the equation (8):

$${NOISE}_{M} = {V}_{cm} - \frac{{V}_{in , diff}}{2} .$$

In embodiments, Noise_{P} signal is provided at the non-inverted terminal of the comparator 804 and Noise_{M} signal is provided at the inverted terminal of the comparator 804. Regardless of the logic level of the output signal (OUT_COMP) based on Noise_{P} signal and Noise_{M} signal, the mean values of the positive output signal (OUT_{P}), corresponding to the first rectified signal 1102a, and the negative output signal (OUT_{M}), corresponding to the second rectified signal 1102b, remain equal in value.

FIG. 13 illustrates the operation of an embodiment differential full-wave rectifier 900 on the noisy differential voltage (Vᵢₙ) signal 502 after it is rectified and filtered as the first rectified and filtered signal 1104a and the second rectified and filtered signal 1104b. The input to the positive-side buffer circuit 906 is the first rectified and filtered signal 1104a. The input to the negative-side buffer circuit 908 is the second rectified and filtered signal 1104b.

Regardless of the logic level of the output signal (OUT_COMP) based on Noise_{P} signal and Noise_{M} signal, the DC values of the positive output signal (OUT_{P}) and the negative output signal (OUT_{M}) remain the same. Accordingly, as the first differential rectified and filtered signal 1106a is substantially equal in magnitude and shape to the second differential rectified and filtered signal 1106b, the subtraction of the two signals results in a null signal.

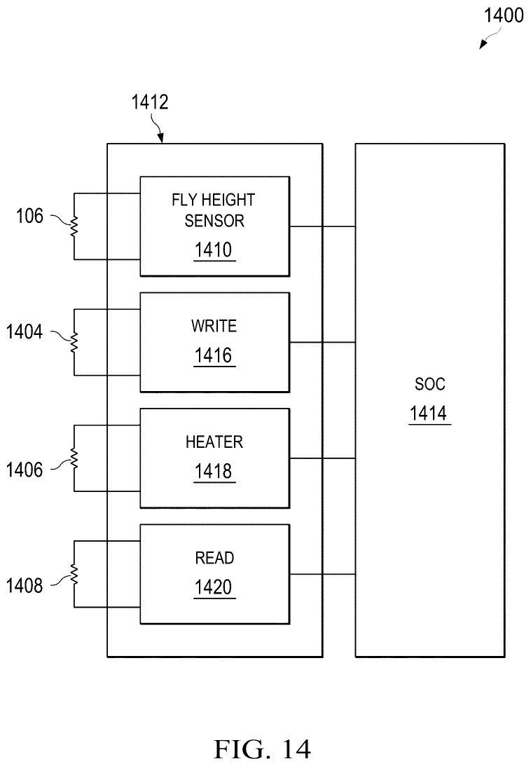

FIG. 14 illustrates a block diagram of a pre-amplifier 1412 that is placed on the disk drive head stack assembly of a hard disk drive. The disk drive head stack assembly slides over the disk. The pre-amplifier 1412 includes the fly height sensor 1410. In embodiments, the fly height sensor 1410 includes a biasing circuit and an amplifier (not shown). The fly height sensor 1410 is coupled to the resistive sensor 106.

A write resistor 1404 is coupled to the write circuit 1416 (for writing to the disk), a heater resistor 1406 is coupled to the heater circuit 1418 (for controlling the fly height spacing), and a read resistor 1408 is coupled to the read circuit 1420 (for reading from the disk). The fly height sensor 1410, write circuit 1416, heater circuit 1418, and read circuit 1420 are coupled to a silicon-on-chip (SoC) 1414 for processing.

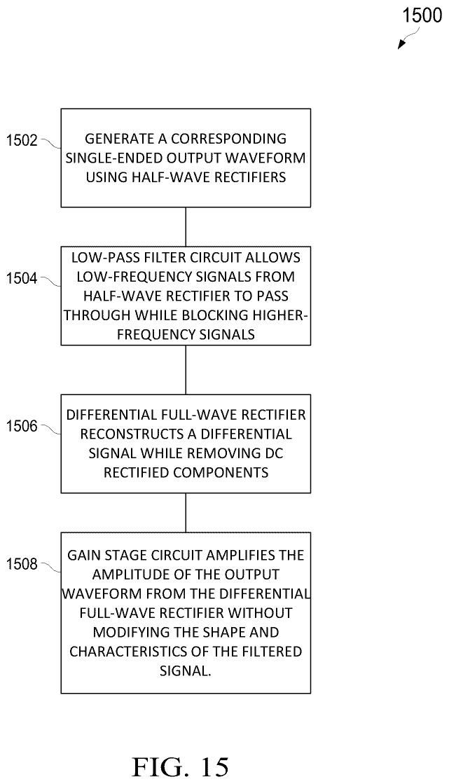

FIG. 15 illustrates a flow chart of an embodiment method 1500 for operating an envelope detector circuit 600. It is noted that all steps outlined are not necessarily required and can be optional. Further, changes to the arrangement of the steps, removal of one or more steps and path connections, and addition of steps and path connections are similarly contemplated.

At step 1502, each half-wave rectifier 602a-b generates a corresponding single-ended output waveform with positive voltage with minimal distortion. In embodiments, half-wave rectifier 602 operates at up to tens of megahertz (MHz). A first half-wave rectifier 602a allows positive half-cycles of the differential voltage (Vᵢₙ) to pass through while blocking negative half-cycles (i.e., series of positive half-cycles with the negative half-cycles removed). A second half-wave rectifier 602b allows negative half-cycles of the differential voltage (Vᵢₙ) to pass through while blocking positive half-cycles (i.e., series of negative half-cycles with the positive half-cycles removed, where the polarity of the negative half-cycles are reversed). Each half-wave rectifier 602a-b generates a corresponding single-ended output waveform with the same positive polarity for the half-cycle it passes through, but phase-shifted by 180°.

At step 1504, the low-pass filter circuit 604 allows low-frequency signals from the half-wave rectifier 602 to pass through while attenuating or blocking higher-frequency signals. In embodiments, low-pass filter circuit 604 is a second-order low-pass filter. In embodiments, low-pass filter circuit 604 is adjustable, and the cut-off frequency (f_{c}) of low-pass filter circuit 604 can be adjusted from, for example, tens of kilohertz (kHz) to hundreds of kHz.

In the case of the high-frequency zero-mean value differential voltage (Vᵢₙ) signal (i.e., the frequency (fₛ) of the zero-mean value differential voltage (Vᵢₙ) signal being much greater than the cut-off frequency (f_{c}) of the low-pass filter circuit), the output of each low-pass filter circuit 604a-b is a DC signal with the same amplitude.

At step 1506, the differential full-wave rectifier 606 reconstructs a differential signal from the low-pass filter circuit 604 while removing the DC rectified components and achieving full rectification of the input signals. In embodiments, the differential full-wave rectifier 606 is configured to operate at up to tens of megahertz (MHz).

At step 1508, the gain stage circuit 608 amplifies the amplitude of the output waveform from the differential full-wave rectifier 606 without modifying the shape and characteristics of the filtered signal. In embodiments, the gain stage circuit 608 is configured to have selectable gain. The envelope detector, thus, capture the intensity changes of the differential voltage (Vᵢₙ) from the gain stage circuit 112 and extracts the amplitude or magnitude (Vₒᵤₜ) without the deficiencies in the conventional envelope detector circuit 200.

A first aspect relates to an envelope detector circuit for detecting an envelope of a signal from a sensor in a pre-amplifier circuit of a hard disk drive. The envelope detector circuit includes a half-wave rectifier, a low-pass filter, and a differential full-wave rectifier. The half-wave rectifier is configured to receive a differential voltage from the sensor indicating a fly height of the hard disk drive and generate a pair of single-ended output waveforms based on the differential voltage. Each pair of single-ended output waveforms has a positive polarity for a half-cycle it passes through. The low-pass filter includes a first low-pass filter and a second low-pass filter. The low-pass filter allows low-frequency signals from the pair of single-ended output waveforms to pass through while attenuating or blocking higher-frequency signals. The differential full-wave rectifier is configured to reconstruct a differential signal from the low-pass filter while removing DC rectified components.

In a first implementation form of the envelope detector circuit according to the first aspect as such, the low-pass filter is a second-order low-pass filter and a cut-off frequency of the low-pass filter is adjustable.

In a second implementation form of the envelope detector circuit according to the first aspect as such or any preceding implementation form of the first aspect, the envelope detector circuit further includes a gain stage circuit coupled to an output terminal of the differential full-wave rectifier. The gain stage circuit is configured to amplify an output signal of the differential full-wave rectifier.

In a third implementation form of the envelope detector circuit according to the first aspect as such or any preceding implementation form of the first aspect, a gain value of the gain stage circuit is selectable from a range of gain values.

In a fourth implementation form of the envelope detector circuit according to the first aspect as such or any preceding implementation form of the first aspect, the half-wave rectifier includes a comparator configured to generate a binary signal based on a difference between a singled-ended positive side of the differential voltage at a non-inverted terminal of the comparator and a single-ended negative side of the differential voltage at an inverted terminal of the comparator; an inverter configured to invert the binary signal from the comparator to generate an inverted binary signal; a first buffer configured to receive the singled-ended positive side of the differential voltage; a second buffer configured to receive the single-ended negative side of the differential voltage; a first resistor coupled to an output terminal of the first buffer; a second resistor coupled to an output terminal of the second buffer, the first resistor and the second resistor coupled at a common node having a common-mode voltage; a first transistor configured to pass through an output signal of the first buffer at a first output terminal of the half-wave rectifier based on the binary signal; a second transistor configured to pass through the common-mode voltage at the first output terminal of the half-wave rectifier based on the inverted binary signal; a third transistor configured to pass through an output signal of the second buffer at a second output terminal of the half-wave rectifier based on the inverted binary signal; and a fourth transistor configured to pass through the common-mode voltage at the second output terminal of the half-wave rectifier based on the binary signal.

In a fifth implementation form of the envelope detector circuit according to the first aspect as such or any preceding implementation form of the first aspect, the differential full-wave rectifier includes a comparator configured to generate a binary signal based on a difference between a singled-ended positive-side of the differential voltage at a non-inverted terminal of the comparator and a singled-ended negative-side of the differential voltage at an inverted terminal of the comparator; an inverter configured to invert the binary signal from the comparator to generate an inverted binary signal; a first buffer coupled to a first output of the low-pass filter configured to receive a first filtered signal of a first single-ended signal of the pair of single-ended output waveforms; a second buffer coupled to a second output of the low-pass filter configured to receive a second filtered signal of a second single-ended signal of the pair of single-ended output waveforms; a first transistor configured to pass through an output signal of the first buffer at a first output terminal of the differential full-wave rectifier based on the binary signal; a second transistor configured to pass through the output signal of the first buffer at a second output terminal of the differential full-wave rectifier based on the inverted binary signal; a third transistor configured to pass through an output signal of the second buffer at the second output terminal of the differential full-wave rectifier based on the binary signal; and a fourth transistor configured to pass through the output signal of the second buffer at the first output terminal of the differential full-wave rectifier based on the inverted binary signal.

In a sixth implementation form of the envelope detector circuit according to the first aspect as such or any preceding implementation form of the first aspect, the differential signal reconstructed from the low-pass filter is used to operate the hard disk drive.

A second aspect relates to a pre-amplifier circuit of a hard disk drive, the pre-amplifier circuit includes a sensor configured to measure a fly height of the hard disk drive; a half-wave rectifier configured to receive a differential voltage from the sensor indicating the fly height of the hard disk drive and generate a pair of single-ended output waveforms based on the differential voltage, each of the pair of single-ended output waveforms having a positive polarity for a half-cycle it passes through; a low-pass filter comprising a first low-pass filter and a second low-pass filter, the low-pass filter being configured to allow low-frequency signals from the pair of single-ended output waveforms to pass through while attenuating or blocking higher-frequency signals; and a differential full-wave rectifier configured to reconstruct a differential signal from the low-pass filter while removing DC rectified components.

In a first implementation form of the pre-amplifier circuit according to the second aspect as such, the low-pass filter is a second-order low-pass filter and a cut-off frequency of the low-pass filter is adjustable.

In a second implementation form of the pre-amplifier circuit according to the second aspect as such or any preceding implementation form of the second aspect, the pre-amplifier circuit further includes a gain stage circuit coupled to an output terminal of the differential full-wave rectifier. The gain stage circuit is configured to amplify an output signal of the differential full-wave rectifier.

In a third implementation form of the pre-amplifier circuit according to the second aspect as such or any preceding implementation form of the second aspect, a gain value of the gain stage circuit is selectable from a range of gain values.

In a fourth implementation form of the pre-amplifier circuit according to the second aspect as such or any preceding implementation form of the second aspect, the half-wave rectifier includes a comparator configured to generate a binary signal based on a difference between a singled-ended positive side of the differential voltage at a non-inverted terminal of the comparator and a singled-ended negative side of the differential voltage at an inverted terminal of the comparator; an inverter configured to invert the binary signal from the comparator to generate an inverted binary signal; a first buffer configured to receive the singled-ended positive side of the differential voltage; a second buffer configured to receive the singled-ended negative side of the differential voltage; a first resistor coupled to an output terminal of the first buffer; a second resistor coupled to an output terminal of the second buffer, the first resistor and the second resistor coupled at a common node having a common-mode voltage; a first transistor configured to pass through an output signal of the first buffer at a first output terminal of the half-wave rectifier based on the binary signal; a second transistor configured to pass through the common-mode voltage at the first output terminal of the half-wave rectifier based on the inverted binary signal; a third transistor configured to pass through an output signal of the second buffer at a second output terminal of the half-wave rectifier based on the inverted binary signal; and a fourth transistor configured to pass through the common-mode voltage at the second output terminal of the half-wave rectifier based on the binary signal.

In a fifth implementation form of the pre-amplifier circuit according to the second aspect as such or any preceding implementation form of the second aspect, the differential full-wave rectifier includes a comparator configured to generate a binary signal based on a difference between a singled-ended positive side of the differential voltage at a non-inverted terminal of the comparator and a singled-ended negative side of the differential voltage at an inverted terminal of the comparator; an inverter configured to invert the binary signal from the comparator to generate an inverted binary signal; a first buffer coupled to a first output of the low-pass filter configured to receive a first filtered signal of a first single-ended signal of the pair of single-ended output waveforms; a second buffer coupled to a second output of the low-pass filter configured to receive a second filtered signal of a second single-ended signal of the pair of single-ended output waveforms; a first transistor configured to pass through an output signal of the first buffer at a first output terminal of the differential full-wave rectifier based on the binary signal; a second transistor configured to pass through the output signal of the first buffer at a second output terminal of the differential full-wave rectifier based on the inverted binary signal; a third transistor configured to pass through an output signal of the second buffer at the second output terminal of the differential full-wave rectifier based on the binary signal; and a fourth transistor configured to pass through the output signal of the second buffer at the first output terminal of the differential full-wave rectifier based on the inverted binary signal.

In a sixth implementation form of the pre-amplifier circuit according to the second aspect as such or any preceding implementation form of the second aspect, the differential signal reconstructed from the low-pass filter is used to operate the hard disk drive.

A third aspect relates to a method for detecting an envelope of a signal from a sensor in a pre-amplifier circuit of a hard disk drive. The method includes receiving, by a half-wave rectifier, a differential voltage from the sensor indicating a fly height of the hard disk drive; generating, by the half-wave rectifier, a pair of single-ended output waveforms based on the differential voltage, each of the pair of single-ended output waveforms having a positive polarity for a half-cycle it passes through; filtering, by a low-pass filter, high-frequency signals from the pair of single-ended output waveforms while passing through low-frequency signals; and reconstructing, by a differential full-wave rectifier, a differential signal from the low-pass filter while removing DC rectified components.

In a first implementation form of the method according to the third aspect as such, the low-pass filter is a second-order low-pass filter and a cut-off frequency of the low-pass filter is adjustable.

In a second implementation form of the method according to the third aspect as such or any preceding implementation form of the third aspect, the method further includes amplifying, by a gain stage circuit, an output signal of the differential full-wave rectifier.

In a third implementation form of the method according to the third aspect as such or any preceding implementation form of the third aspect, a gain value of the gain stage circuit is selectable from a range of gain values.

In a fourth implementation form of the method according to the third aspect as such or any preceding implementation form of the third aspect, the method further includes generating, by a comparator of the half-wave rectifier, a binary signal based on a difference between a singled-ended positive side of the differential voltage at a non-inverted terminal of the comparator and a singled-ended negative side of the differential voltage at an inverted terminal of the comparator; inverting, by an inverter of the half-wave rectifier, the binary signal from the comparator to generate an inverted binary signal; receiving, by a first buffer of the half-wave rectifier, the single-ended positive side of the differential voltage; receiving, by a second buffer of the half-wave rectifier, the single-ended negative side of the differential voltage, wherein a first resistor is coupled to an output terminal of the first buffer, a second resistor is coupled to an output terminal of the second buffer, the first resistor and the second resistor coupled at a common node having a common-mode voltage; passing through, by a first transistor of the half-wave rectifier, an output signal of the first buffer at a first output terminal of the half-wave rectifier based on the binary signal; passing through, by a second transistor of the half-wave rectifier, the common-mode voltage at the first output terminal of the half-wave rectifier based on the inverted binary signal; passing through, by a third transistor of the half-wave rectifier, an output signal of the second buffer at a second output terminal of the half-wave rectifier based on the inverted binary signal; and passing through, by a fourth transistor of the half-wave rectifier, the common-mode voltage at the second output terminal of the half-wave rectifier based on the binary signal.

In a fifth implementation form of the method according to the third aspect as such or any preceding implementation form of the third aspect, the method further includes generating, by a comparator of the differential full-wave rectifier, a binary signal based on a difference between a single-ended positive side of the differential voltage at a non-inverted terminal of the comparator and a single-ended negative side of the differential voltage at an inverted terminal of the comparator; inverting, by an inverter of the differential full-wave rectifier, the binary signal from the comparator to generate an inverted binary signal; receiving, by a first buffer of the differential full-wave rectifier, a first filtered signal of a first single-ended signal of the pair of single-ended output waveforms; receiving, by a second buffer of the differential full-wave rectifier, a second filtered signal of a second single-ended signal of the pair of single-ended output waveforms; passing through, by a first transistor of the differential full-wave rectifier, an output signal of the first buffer at a first output terminal of the differential full-wave rectifier based on the binary signal; passing through, by a second transistor of the differential full-wave rectifier, the output signal of the first buffer at a second output terminal of the differential full-wave rectifier based on the inverted binary signal; passing through, by a third transistor of the differential full-wave rectifier, an output signal of the second buffer at the second output terminal of the differential full-wave rectifier based on the binary signal; and passing through, by a fourth transistor of the differential full-wave rectifier, the output signal of the second buffer at the first output terminal of the differential full-wave rectifier based on the inverted binary signal.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. An envelope detector circuit for detecting an envelope of a signal from a sensor in a pre-amplifier circuit of a hard disk drive, the envelope detector circuit comprising:
a half-wave rectifier configured to:
receive a differential voltage from the sensor indicating a fly height of the hard disk drive, and
generate a pair of single-ended output waveforms based on the differential voltage, each of the pair of single-ended output waveforms having a positive polarity for a half-cycle it passes through;
a low-pass filter comprising a first low-pass filter and a second low-pass filter, the low-pass filter being configured to allow low-frequency signals from the pair of single-ended output waveforms to pass through while attenuating or blocking higher-frequency signals; and
a differential full-wave rectifier configured to reconstruct a differential signal from the low-pass filter while removing DC rectified components.

2. The envelope detector circuit of claim 1, wherein the low-pass filter is a second-order low-pass filter, and wherein a cut-off frequency of the low-pass filter is adjustable.

3. The envelope detector circuit of claim 1, further comprising a gain stage circuit coupled to an output terminal of the differential full-wave rectifier, the gain stage circuit being configured to amplify an output signal of the differential full-wave rectifier.

4. The envelope detector circuit of claim 3, wherein a gain value of the gain stage circuit is selectable from a range of gain values.

5. The envelope detector circuit of claim 1, wherein the half-wave rectifier comprises:
a comparator configured to generate a binary signal based on a difference between a singled-ended positive side of the differential voltage at a non-inverted terminal of the comparator and a single-ended negative side of the differential voltage at an inverted terminal of the comparator;
an inverter configured to invert the binary signal from the comparator to generate an inverted binary signal;
a first buffer configured to receive the singled-ended positive side of the differential voltage;
a second buffer configured to receive the single-ended negative side of the differential voltage;
a first resistor coupled to an output terminal of the first buffer;
a second resistor coupled to an output terminal of the second buffer, the first resistor and the second resistor coupled at a common node having a common-mode voltage;
a first transistor configured to pass through an output signal of the first buffer at a first output terminal of the half-wave rectifier based on the binary signal;
a second transistor configured to pass through the common-mode voltage at the first output terminal of the half-wave rectifier based on the inverted binary signal;
a third transistor configured to pass through an output signal of the second buffer at a second output terminal of the half-wave rectifier based on the inverted binary signal; and
a fourth transistor configured to pass through the common-mode voltage at the second output terminal of the half-wave rectifier based on the binary signal.

6. The envelope detector circuit of claim 1, wherein the differential full-wave rectifier comprises:
a comparator configured to generate a binary signal based on a difference between a singled-ended positive-side of the differential voltage at a non-inverted terminal of the comparator and a singled-ended negative-side of the differential voltage at an inverted terminal of the comparator;
an inverter configured to invert the binary signal from the comparator to generate an inverted binary signal;
a first buffer coupled to a first output of the low-pass filter configured to receive a first filtered signal of a first single-ended signal of the pair of single-ended output waveforms;
a second buffer coupled to a second output of the low-pass filter configured to receive a second filtered signal of a second single-ended signal of the pair of single-ended output waveforms;
a first transistor configured to pass through an output signal of the first buffer at a first output terminal of the differential full-wave rectifier based on the binary signal;
a second transistor configured to pass through the output signal of the first buffer at a second output terminal of the differential full-wave rectifier based on the inverted binary signal;
a third transistor configured to pass through an output signal of the second buffer at the second output terminal of the differential full-wave rectifier based on the binary signal; and
a fourth transistor configured to pass through the output signal of the second buffer at the first output terminal of the differential full-wave rectifier based on the inverted binary signal.

7. The envelope detector circuit of claim 1, wherein the differential signal reconstructed from the low-pass filter is used to operate the hard disk drive.

8. A pre-amplifier circuit of a hard disk drive, the pre-amplifier circuit comprising:
a sensor configured to measure a fly height of the hard disk drive;
a half-wave rectifier configured to:
receive a differential voltage from the sensor indicating the fly height of the hard disk drive, and
generate a pair of single-ended output waveforms based on the differential voltage, each of the pair of single-ended output waveforms having a positive polarity for a half-cycle it passes through;
a low-pass filter comprising a first low-pass filter and a second low-pass filter, the low-pass filter being configured to allow low-frequency signals from the pair of single-ended output waveforms to pass through while attenuating or blocking higher-frequency signals; and
a differential full-wave rectifier configured to reconstruct a differential signal from the low-pass filter while removing DC rectified components.

9. The pre-amplifier circuit of claim 8, wherein the low-pass filter is a second-order low-pass filter, and wherein a cut-off frequency of the low-pass filter is adjustable.

10. The pre-amplifier circuit of claim 8, further comprising a gain stage circuit coupled to an output terminal of the differential full-wave rectifier, the gain stage circuit being configured to amplify an output signal of the differential full-wave rectifier.

11. The pre-amplifier circuit of claim 10, wherein a gain value of the gain stage circuit is selectable from a range of gain values.

12. The pre-amplifier circuit of claim 8, wherein the half-wave rectifier comprises:
a comparator configured to generate a binary signal based on a difference between a singled-ended positive side of the differential voltage at a non-inverted terminal of the comparator and a singled-ended negative side of the differential voltage at an inverted terminal of the comparator;
an inverter configured to invert the binary signal from the comparator to generate an inverted binary signal;
a first buffer configured to receive the singled-ended positive side of the differential voltage;
a second buffer configured to receive the singled-ended negative side of the differential voltage;
a first resistor coupled to an output terminal of the first buffer;
a second resistor coupled to an output terminal of the second buffer, the first resistor and the second resistor coupled at a common node having a common-mode voltage;
a first transistor configured to pass through an output signal of the first buffer at a first output terminal of the half-wave rectifier based on the binary signal;
a second transistor configured to pass through the common-mode voltage at the first output terminal of the half-wave rectifier based on the inverted binary signal;
a third transistor configured to pass through an output signal of the second buffer at a second output terminal of the half-wave rectifier based on the inverted binary signal; and
a fourth transistor configured to pass through the common-mode voltage at the second output terminal of the half-wave rectifier based on the binary signal.

13. The pre-amplifier circuit of claim 8, wherein the differential full-wave rectifier comprises:
a comparator configured to generate a binary signal based on a difference between a singled-ended positive side of the differential voltage at a non-inverted terminal of the comparator and a singled-ended negative side of the differential voltage at an inverted terminal of the comparator;
an inverter configured to invert the binary signal from the comparator to generate an inverted binary signal;
a first buffer coupled to a first output of the low-pass filter configured to receive a first filtered signal of a first single-ended signal of the pair of single-ended output waveforms;
a second buffer coupled to a second output of the low-pass filter configured to receive a second filtered signal of a second single-ended signal of the pair of single-ended output waveforms;
a first transistor configured to pass through an output signal of the first buffer at a first output terminal of the differential full-wave rectifier based on the binary signal;
a second transistor configured to pass through the output signal of the first buffer at a second output terminal of the differential full-wave rectifier based on the inverted binary signal;
a third transistor configured to pass through an output signal of the second buffer at the second output terminal of the differential full-wave rectifier based on the binary signal; and
a fourth transistor configured to pass through the output signal of the second buffer at the first output terminal of the differential full-wave rectifier based on the inverted binary signal.

14. The pre-amplifier circuit of claim 8, wherein the differential signal reconstructed from the low-pass filter is used to operate the hard disk drive.

15. A method for detecting an envelope of a signal from a sensor in a pre-amplifier circuit of a hard disk drive, the method comprising:
receiving, by a half-wave rectifier, a differential voltage from the sensor indicating a fly height of the hard disk drive;
generating, by the half-wave rectifier, a pair of single-ended output waveforms based on the differential voltage, each of the pair of single-ended output waveforms having a positive polarity for a half-cycle it passes through;
filtering, by a low-pass filter, high-frequency signals from the pair of single-ended output waveforms while passing through low-frequency signals; and
reconstructing, by a differential full-wave rectifier, a differential signal from the low-pass filter while removing DC rectified components.

16. The method of claim 15, wherein the low-pass filter is a second-order low-pass filter, and wherein a cut-off frequency of the low-pass filter is adjustable.

17. The method of claim 15, further comprising amplifying, by a gain stage circuit, an output signal of the differential full-wave rectifier.

18. The method of claim 17, wherein a gain value of the gain stage circuit is selectable from a range of gain values.

19. The method of claim 15, further comprising:
generating, by a comparator of the half-wave rectifier, a binary signal based on a difference between a singled-ended positive side of the differential voltage at a non-inverted terminal of the comparator and a singled-ended negative side of the differential voltage at an inverted terminal of the comparator;
inverting, by an inverter of the half-wave rectifier, the binary signal from the comparator to generate an inverted binary signal;
receiving, by a first buffer of the half-wave rectifier, the single-ended positive side of the differential voltage;
receiving, by a second buffer of the half-wave rectifier, the single-ended negative side of the differential voltage, wherein a first resistor is coupled to an output terminal of the first buffer, a second resistor is coupled to an output terminal of the second buffer, the first resistor and the second resistor coupled at a common node having a common-mode voltage;
passing through, by a first transistor of the half-wave rectifier, an output signal of the first buffer at a first output terminal of the half-wave rectifier based on the binary signal;
passing through, by a second transistor of the half-wave rectifier, the common-mode voltage at the first output terminal of the half-wave rectifier based on the inverted binary signal;
passing through, by a third transistor of the half-wave rectifier, an output signal of the second buffer at a second output terminal of the half-wave rectifier based on the inverted binary signal; and
passing through, by a fourth transistor of the half-wave rectifier, the common-mode voltage at the second output terminal of the half-wave rectifier based on the binary signal.

20. The method of claim 15, further comprising:
generating, by a comparator of the differential full-wave rectifier, a binary signal based on a difference between a single-ended positive side of the differential voltage at a non-inverted terminal of the comparator and a single-ended negative side of the differential voltage at an inverted terminal of the comparator;
inverting, by an inverter of the differential full-wave rectifier, the binary signal from the comparator to generate an inverted binary signal;
receiving, by a first buffer of the differential full-wave rectifier, a first filtered signal of a first single-ended signal of the pair of single-ended output waveforms;
receiving, by a second buffer of the differential full-wave rectifier, a second filtered signal of a second single-ended signal of the pair of single-ended output waveforms;
passing through, by a first transistor of the differential full-wave rectifier, an output signal of the first buffer at a first output terminal of the differential full-wave rectifier based on the binary signal;
passing through, by a second transistor of the differential full-wave rectifier, the output signal of the first buffer at a second output terminal of the differential full-wave rectifier based on the inverted binary signal;
passing through, by a third transistor of the differential full-wave rectifier, an output signal of the second buffer at the second output terminal of the differential full-wave rectifier based on the binary signal; and
passing through, by a fourth transistor of the differential full-wave rectifier, the output signal of the second buffer at the first output terminal of the differential full-wave rectifier based on the inverted binary signal.
